(19) United States
(12) Patent Application Publication
(10) Pub. No.: US 2024/0267018 A1
(43) Pub. Date: Aug. 8, 2024

(54) PIEZOELECTRIC FILM BULK ACOUSTIC RESONATOR

(71) Applicant: AAC Technologies (Nanjing) Co., Ltd., Nanjing (CN)

(72) Inventors: Zhang Zhang, Nanjing (CN); Shuai Yang, Nanjing (CN); Ke Wu, Nanjing (CN); Zhiqiang Zhuang, Nanjing (CN); Lirong Zhang, Nanjing (CN); Chao Wang, Nanjing (CN)

(21) Appl. No.: 18/334,364

(22) Filed: Jun. 13, 2023

Related U.S. Application Data
(63) Continuation of application No. PCT/CN2023/081487, filed on Mar. 15, 2023.

(30) Foreign Application Priority Data
Feb. 2, 2023 (CN) 202310073492.6

(51) Int. Cl. H03H 9/02; H03H 9/17

(52) U.S. Cl. CPC H03H 9/02118; H03H 9/02015; H03H 9/171

(57) ABSTRACT

A piezoelectric film bulk acoustic resonator includes a substrate, a bottom electrode located on one side of the substrate, a piezoelectric layer covering one side of the bottom electrode away from the substrate, a top electrode located on one side of the piezoelectric layer away from the bottom electrode, an etching insertion layer located on one side of the top electrode away from the piezoelectric layer, and a protruding frame located on one side of the etching insertion layer away from the top electrode. At least one of the etching insertion layer and the protruding frame is provided with an extending portion. By setting the extending portion, a first extreme point, a second extreme point and a third extreme point of the quality factor of the piezoelectric film bulk acoustic resonator are obviously larger than those of the related art.

### TECHNICAL FIELD

The present invention relates to a technical field of resonators, in particular to a piezoelectric film bulk acoustic resonator.

### BACKGROUND

Piezoelectric film bulk acoustic resonators are resonators manufactured using silicon substrate, micro-electro-mechanical system (MEMS), and thin film technologies, which can achieve functions of image cancellation, parasitic filtering, channel selection, etc. in wireless transceivers.

Current piezoelectric film bulk acoustic resonators each includes a substrate, a bottom electrode, a piezoelectric layer, a top electrode, an etching insertion layer, and a ring-shaped protruding frame stacked along a thickness direction of the piezoelectric film bulk acoustic resonator, an overlapping area of the bottom electrode, the piezoelectric layer, the top electrode, and the etching insertion layer constitutes an effective source area of the piezoelectric film bulk acoustic resonator, along the thickness direction of the piezoelectric film bulk acoustic resonator, a projection contour of the protruding frame is located at an edge of the effective source area, and the protruding frame is configured to reflect a part of transverse propagating Rayleigh Lamb waves (RL waves) back into the effective source area.

The RL waves mainly have four modes of S0, A0, S1, and A1, and each of the four modes has a different wavelength. When a width of the protruding frame is equal to an odd multiple of ¼ of a wavelength of one RL wave in a certain mode, a reflective efficiency of the protruding frame is the highest, since the width of the protruding frame is not adjustable after production and processing, the protruding frame may only reflect the RL wave in a single mode. When the RL wave is in other modes, an energy leakage at an edge of the effective source area is large, thereby resulting in a lower quality factor of the piezoelectric film bulk acoustic resonator.

Therefore, it is necessary to provide a piezoelectric film bulk acoustic resonator with a high quality factor.

### SUMMARY

The present invention aims to provide a piezoelectric film bulk acoustic resonator with a high quality factor.

The technical solutions of the present invention are as follows.

The piezoelectric film bulk acoustic resonator includes a substrate, a bottom electrode, a piezoelectric layer, a top electrode, an etching insertion layer and a protruding frame arranged along a thickness direction of the piezoelectric film bulk acoustic resonator. The bottom electrode is located on one side of the substrate, the piezoelectric layer covers one side of the bottom electrode away from the substrate, the top electrode is located on one side of the piezoelectric layer away from the bottom electrode, the etching insertion layer is located on one side of the top electrode away from the piezoelectric layer, and the protruding frame is located on one side of the etching insertion layer away from the top electrode. A stacking area of the bottom electrode, the piezoelectric layer, the top electrode, and the etching insertion layer constitutes at least part of an effective source area of the piezoelectric film bulk acoustic resonator. An extending portion is disposed on at least one of the etching insertion layer and the protruding frame, the extending portion is located at an edge of the effective source area, and the extending portion extends towards a direction away from the effective source area along a direction perpendicular to the thickness direction of the piezoelectric thin film bulk acoustic resonator.

Furthermore, a first projection contour of the extending portion is located within a second projection contour of the bottom electrode along the thickness direction of the piezoelectric film bulk acoustic resonator.

Furthermore, an extension length L of the extending portion along the direction perpendicular to the thickness direction of the piezoelectric film bulk acoustic resonator satisfies:

$$L ⩾ 0.5 μm .$$

Furthermore, the extension portion includes a first extension portion and a second extension portion, the first extending portion is disposed on the etching insertion layer, and the second extending portion is disposed on the protruding frame. A first extension length of the first extending portion is the same or different from a second extension length of the second extending portion along an extension direction of the extending portion.

Furthermore, the substrate defines a cavity, the cavity passes through the one side of the substrate along the thickness direction of the piezoelectric film bulk acoustic resonator, and the bottom electrode covers the cavity.

Furthermore, a size of a projection of the bottom electrode towards the substrate along the thickness direction of the piezoelectric film bulk acoustic resonator is equal to or greater than a size of the cavity. A size of a projection of the top electrode towards the substrate along the thickness direction of the piezoelectric film bulk acoustic resonator is less than or equal to the size of the cavity.

Furthermore, the etching insertion layer includes a dielectric material, the dielectric material is aluminum nitride or silicon nitride.

Furthermore, the protruding frame includes a first metal material, the first metal material includes one of aluminum, molybdenum, tungsten, and ruthenium, or the first metal material is a composite metal formed by at least two of the aluminum, the molybdenum, the tungsten, and the ruthenium.

Furthermore, the bottom electrode includes a second metal material, the second metal material includes one of aluminum, molybdenum, tungsten, and ruthenium, or the second metal material is a composite metal formed by at least two of the aluminum, the molybdenum, the tungsten, and the ruthenium. The top electrode includes a third metal material, the third metal material includes one of the aluminum, the molybdenum, the tungsten, and the ruthenium, or the third metal material is a composite metal formed by at least two of the aluminum, the molybdenum, the tungsten, and the ruthenium.

Furthermore, the piezoelectric layer includes a piezoelectric material, the piezoelectric material is one of aluminum nitride, zinc oxide, titanium lead zirconate, lithium niobate and lithium tantalate, or the piezoelectric material is a composite piezoelectric material formed by at least two of the aluminum nitride, the zinc oxide, the titanium lead zirconate, the lithium niobate and the lithium tantalate.

The beneficial effects of the present invention are as following.

By setting the extending portion, a first extreme point, a second extreme point, and a third extreme point of a quality factor of the piezoelectric film bulk acoustic resonator are obviously larger than those of the related art, and the increase of the first extreme point is the largest. In addition, since the extending portion does not additionally reduce the effective electro-mechanical coupling factor (k2eff) of the piezoelectric film bulk acoustic resonator, selecting the width of the smaller protruding frame corresponding to the first extreme point results in both a high quality factor and a large effective electro-mechanical coupling factor (k2eff) of the piezoelectric film bulk acoustic resonator.

### BRIEF DESCRIPTION OF DRAWINGS

FIG. 1 is a schematic diagram of a piezoelectric film bulk acoustic resonator according to one embodiment of the present invention.

FIG. 2 is a schematic diagram of a top view of FIG. 1.

FIG. 3 is a schematic diagram of a cross-sectional view of a thickness direction of the piezoelectric film bulk acoustic resonator of FIG. 1.

FIG. 4 is a schematic diagram of the piezoelectric film bulk acoustic resonator according to another embodiment of the present invention.

FIG. 5 is a schematic diagram of a top view of FIG. 4.

FIG. 6 is a schematic diagram of a cross-sectional view of the thickness direction of the piezoelectric film bulk acoustic resonator of FIG. 4.

FIG. 7 is a schematic diagram of an etching insertion layer according to one embodiment shown in FIG. 4.

FIG. 8 is a schematic diagram of a top view of FIG. 7.

FIG. 9 is a schematic diagram of a protruding frame according to one embodiment shown in FIG. 4.

FIG. 10 is a schematic diagram of a top view of FIG. 9.

FIG. 11 illustrates a comparison curve of a quality factor of the piezoelectric film bulk acoustic resonator of the present invention and a quality factor of a piezoelectric film bulk acoustic resonator of the related art.

FIG. 12 illustrates a comparison curve of an effective electro-mechanical coupling factor (k2eff) of the piezoelectric film bulk acoustic resonator of the present invention and an effective electro-mechanical coupling factor (k2eff) of the piezoelectric film bulk acoustic resonator of the related art.

Reference numerals in the drawings: 1. substrate; 11. cavity; 2. bottom electrode; 3. piezoelectric layer; 4. top electrode; 5. etching insertion layer; 51. first extending portion; 52. first accommodating space; 6. protruding frame; 61. second extending portion; 62. second accommodating space; 63. third accommodating space; S1. effective source area; S11. first area; S12. second area; S2. third area; S3. fourth area.

### DETAILED DESCRIPTION

The present invention is further explained in conjunction with the accompanying drawings and implementation methods.

The present invention provides a piezoelectric film bulk acoustic resonator. It can be understood that an external contour of the piezoelectric film bulk acoustic resonator may be rectangular, pentagon, hexagon, ellipse or other deformation structures. The present invention takes a rectangular external contour of the piezoelectric film bulk acoustic resonator as an example.

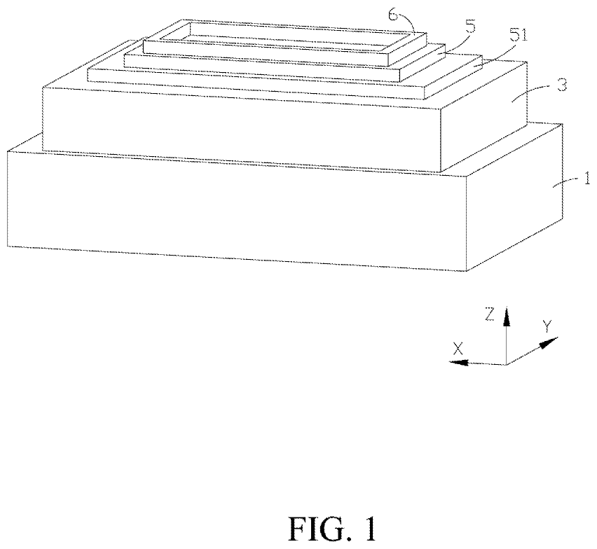

As shown in FIGS. 1 to 6, the piezoelectric film bulk acoustic resonator includes a substrate 1, the piezoelectric film bulk acoustic resonator further includes a bottom electrode 2, a piezoelectric layer 3, a top electrode 4, an etching insertion layer 5, and a protruding frame 6 arranged along a thickness direction of the piezoelectric film bulk acoustic resonator, the bottom electrode 2 is located on one side of the substrate 1, the piezoelectric layer 3 covers one side of the bottom electrode 2 away from the substrate 1, the top electrode 4 is located on one side of the piezoelectric layer 3 away from the bottom electrode 2, the etching insertion layer 5 is located on one side of the top electrode 4 away from the piezoelectric layer 3, and the protruding frame 6 is located on one side of the etching insertion layer 5 away from the top electrode 4. A stacking area of the bottom electrode 2, the piezoelectric layer 3, the top electrode 4, and the etching insertion layer 5 constitutes at least one part of an effective source area S1 of the piezoelectric film bulk acoustic resonator. It can be understood that an extending portion is disposed on at least one of the etching insertion layer 5 and the protruding frame 6, the extending portion is located at an edge of the effective source area S1, the extending portion extends towards a direction away from the effective source area S1 along a direction perpendicular to the thickness direction of the piezoelectric thin film bulk acoustic resonator.

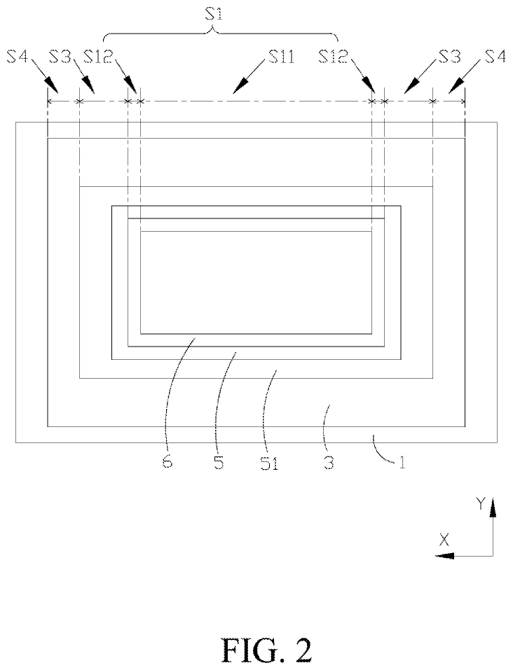

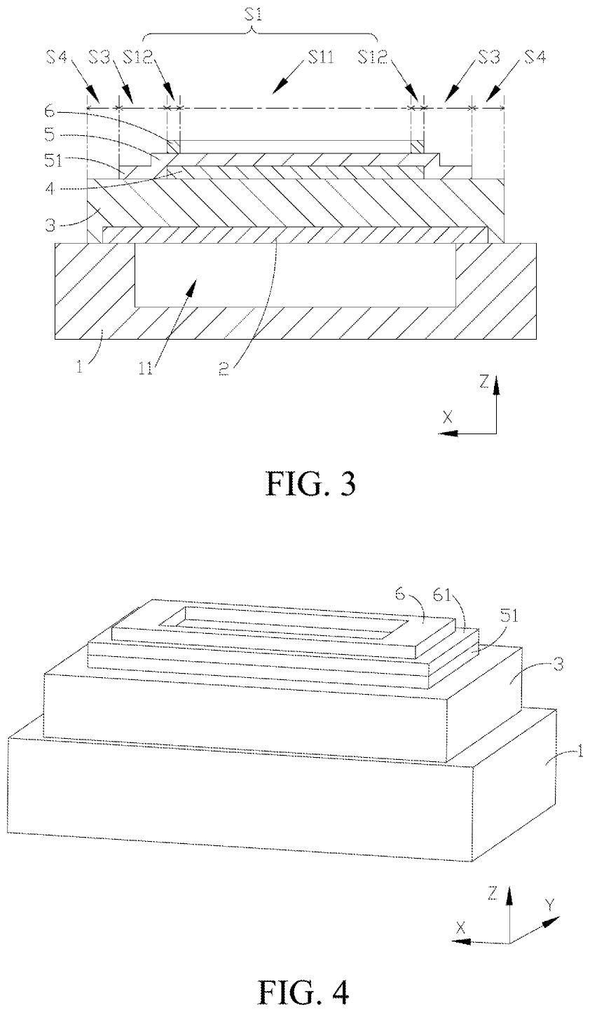

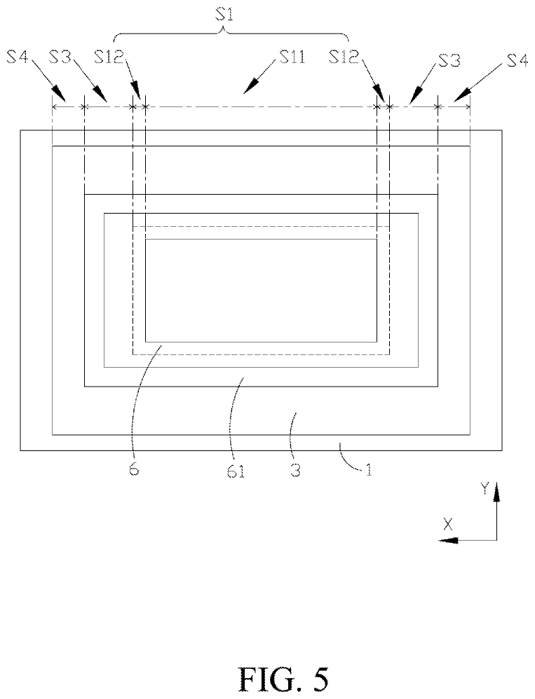

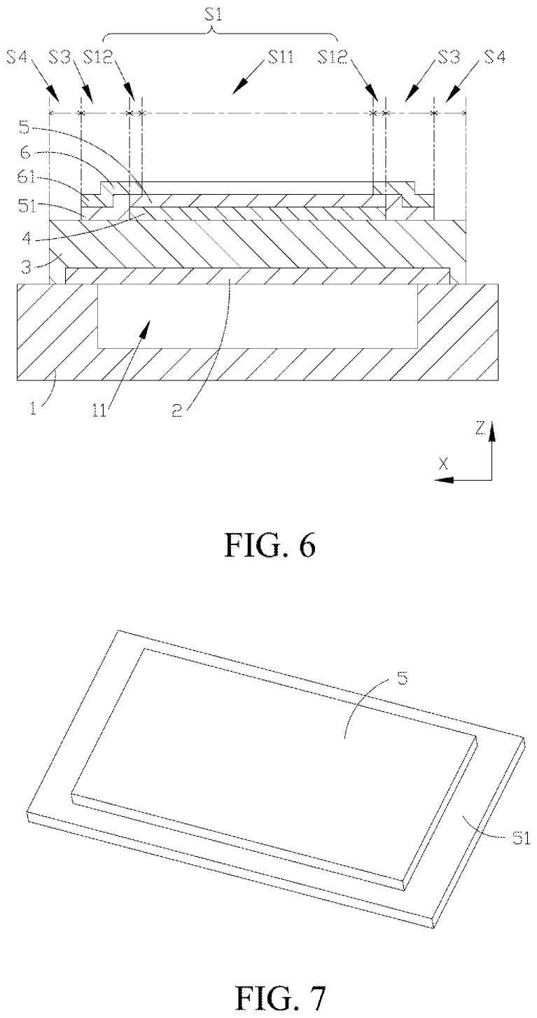

As shown in FIG. 2, FIG. 3, FIG. 5, and FIG. 6, the effective source area S1 includes a first area S11 and a second area S12, in a plane enclosed by a length direction X and a width direction Y of the piezoelectric film bulk acoustic resonator (for the convenience of description, a horizontal plane is used as an example), the first area S11 is located in a middle part of the protruding frame 6, which is an exposed part of the top electrode 4, the second area S12 is a part from an inner edge of the protruding frame 6 to an outer edge of the top electrode 4, a part from the outer edge of the top electrode 4 to an outer edge of the extending portion is a third area S2, and a part from the outer edge of the extending portion to an outer edge of the piezoelectric layer 3 is a fourth area S3.

When the piezoelectric film bulk acoustic resonator works, the bottom electrode 2 and the top electrode 4 are respectively connected to a power supply, the power supply applies an alternating current to the top electrode 4 and the bottom electrode 2, causing the top electrode 4 and the bottom electrode 2 to drive the vibration of the piezoelectric layer 3, thereby generating effective sound waves propagating along the thickness direction Z of the piezoelectric film bulk acoustic resonator, and Rayleigh Lamb waves (RL waves) propagating along the length direction X and/or the width direction Y (i.e., transverse propagation) of the piezoelectric film bulk acoustic resonator.

When a width of the protruding frame 6 is determined, most of the energy of the RL wave of a single mode matching the width of the protruding frame 6 may be reflected back to the effective source area S1 from an edge of the second area S12 and the third area S2 (for the convenience of description, S0 mode is taken as an example to explain below), thereby reducing the energy leakage of the RL wave in S0 mode from the edge of effective source area S1. A part of the energy of the RL wave in A0 mode, S1 mode, and A1 mode may propagate to the third area S2, since the acoustic impedance between the third area S2 and the fourth area S3 is different, and the leakage of the RL waves in the A0 mode, the S1 mode, and the A1 mode may be reflected back to the effective source area S1 from edges of the third area S2 and the fourth area S3, and may be converted into a piston sound wave mode (i.e. effective sound wave) propagated along the thickness direction Z of the piezoelectric film bulk acoustic resonator, thereby reducing the energy leakage of the RL waves in the A0 mode, the S1 mode, and the A1 mode from the edge of the effective source area S1, and effectively improving the quality factor of the piezoelectric film bulk acoustic resonators. The present invention increases the reflection of the RL waves, reduces the limitations of the use of the piezoelectric film bulk acoustic resonator, and improves the working performance and the applicability of the piezoelectric film bulk acoustic resonator by installing an extending portion on the protruding frame 6 and/or the etching insertion layer 5.

Specifically, an extension length of the extending portion may be adjusted to adjust the reflection coefficient of the sound waves reflected by the RL waves in the A0 mode, the S1 mode, and the A1 mode and the conversion efficiency from the RL waves to the effective sound waves.

In addition, since the extending portion is located outside the effective source area S1, there may be no parasitic or load effects, and no additional reduction in the effective electro-mechanical coupling factor (k2eff) of the piezoelectric film bulk acoustic resonator.

Specifically, as shown in FIG. 3 and FIG. 6, along the thickness direction Z of the piezoelectric film bulk acoustic resonator, a projection contour of the extending portion is located within a projection contour of the bottom electrode 2.

In the embodiment, if an outer contour of the extending portion exceeds an outer contour of the bottom electrode 2, the extending portion cannot divide the outside of the effective source area S1 into the third area S2 and the fourth area S3, thus preventing a part of the RL waves from being reflected into the effective source area S1, and further reducing the quality factor of the piezoelectric film bulk acoustic resonator. Therefore, along the thickness direction Z of the piezoelectric film bulk acoustic resonator, the projection contour of the extending portion is located within the projection contour of the bottom electrode 2, which improves the reflection stability of the extending portion towards the RL waves and further improves the quality factor of the piezoelectric film bulk acoustic resonator.

Along the direction perpendicular to the thickness of the piezoelectric film bulk acoustic resonator, i.e., the length direction X and/or the width direction Y of the piezoelectric film bulk acoustic resonator, the extension length L of the extending portion satisfies L≥0.5 μm, specifically, the extension length L of the extending portion may be 0.5 μm, 1 μm, 1.5 μm, 2 μm, 2.6 μm, 3 μm, etc.

If the extension length of the extending portion is small, i.e., L<0.5 μm, the energy of the RL waves that can be reflected by the extending portion is less. Therefore, the condition of L≥0.5 μm may enhance the reflection effect of the extending portion on the RL waves, increase the energy of the RL waves reflected by the extending portion, and further improve the quality factor of the piezoelectric film bulk acoustic resonator.

In one embodiment, as shown in FIG. 1, FIG. 2, and FIG. 3, only the etching insertion layer 5 is provided with an extending portion to simplify the structure of the protruding frame 6 and reduce the processing cost of the protruding frame 6.

It can be understood that the extending portion and the etching insertion layer 5 are integrally formed or arranged separately to increase the structural flexibility of the extending portion and the etching insertion layer 5. The material of the extending portion and the etching insertion layer 5 may be the same or different to increase the replaceability of the extending portion and the etching insertion layer 5, thereby reducing the processing and maintenance costs of the extending portion and the etching insertion layer 5.

In another embodiment, only the protruding frame 6 is provided with an extending portion to simplify the structure of the etching insertion layer 5 and reduce the processing cost of the etching insertion layer 5.

It can be understood that the extending portion and the protruding frame 6 are integrally formed or arranged separately to increase the structural flexibility of the extending portion and the protruding frame 6. The material of the extending portion and the protruding frame 6 may be the same or different to increase the replaceability of the extending portion and the protruding frame 6, thereby reducing the processing and maintenance costs of the extending portion and the protruding frame 6.

In another embodiment, as shown in FIG. 4, FIG. 5, and FIG. 6, both the etching insertion layer 5 and the protruding frame 6 are provided with an extending portion. The extending portion on the etching insertion layer 5 is a first extending portion 51, and the extending portion on the protruding frame 6 is a second extending portion 61.

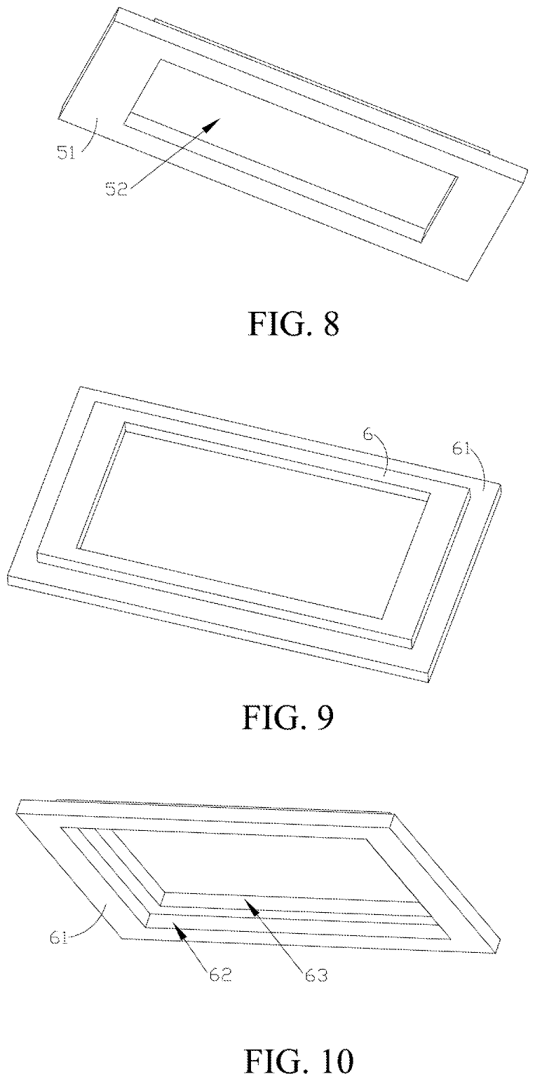

Specifically, as shown in FIG. 7 and FIG. 8, the etching insertion layer 5 defines a first accommodating space 52, along the thickness direction Z of the piezoelectric film bulk acoustic resonator, the first accommodating space 52 passes through the one side of the etching insertion layer 5, as shown in FIG. 6, the top electrode 4 is installed in the first accommodating space 52, and an edge of the top electrode 4 is in contact with a side wall of the first accommodating space 52. An edge of the etching insertion layer 5 at an opening of the first accommodating space 52 extends along the length direction X and/or the width direction Y of the piezoelectric film bulk acoustic resonator to form the first extending portion 51, as shown in FIG. 6, the first extending portion 51 is abutted with the piezoelectric layer 3, and the top electrode 4 is clamped and fixed by the piezoelectric layer 3 and the etching insertion layer 5.

As shown in FIG. 9 and FIG. 10, the protruding frame 6 includes a second accommodating space 62 and a third accommodating space 63 arranged relative to the thickness direction Z of the piezoelectric film bulk acoustic resonator, the second accommodating space 62 passes through one side of the protruding frame 6, the third accommodating space 63 passes through another side of the protruding frame 6, and the second accommodating space 63 is communicated with the third accommodating space 63, the edge of the protruding frame 6 at an opening of the second accommodating space 62 extends along the length direction X and/or the width direction Y of the piezoelectric film bulk acoustic resonator to form the second extending portion 61. As shown in FIG. 6, a part of the etching insertion layer 5 is located within the second accommodating space 62 and abutted with a side wall of the second accommodating space 62, the second extending portion 61 is abutted with the first extending portion 51, a part of the etching insertion layer 5 is exposed through the third accommodating space 63, and an area enclosed by the third accommodating space 63 is the first area S11 of the effective source area S1.

Along the extension direction of the extending portion, i.e., along the length direction X and/or the width direction Y of the piezoelectric film bulk acoustic resonator, the extension length of the first extending portion 51 and the extension length of the second extending portion 61 may be the same or different to increase the structural flexibility of the first extending portion 51 and the second extending portion 61. In the embodiment, the edges of the first extending portion 51 and the second extending portion 61 are located in the same plane in the thickness direction Z of the piezoelectric film bulk acoustic resonator.

In addition, a material of the first extending portion 51 and a material of the second extending portion 61 may be the same or different.

Specifically, the substrate 1 is provided with an acoustic reflection structure, and the acoustic reflection structure can be a closed cavity (not shown in the drawings) formed inside substrate 1; alternatively, as shown in FIG. 3 and FIG. 6, the acoustic reflection structure is a cavity 11 formed on the substrate 1, along the thickness direction Z of the piezoelectric film bulk acoustic resonator, the cavity 11 passes through one side of the substrate 1, and the bottom electrode 2 is covered on the cavity 11; alternatively, the acoustic reflection structure is a Bragg reflector (not shown in the drawings) formed on a surface of the substrate 1.

In the embodiment, the acoustic reflection structure is a sealed cavity 11 inside the substrate 1, a cavity or a Bragg reflector that passes through one side of the substrate 1, which increases the flexibility of the acoustic reflection structure and facilitates flexible setting according to actual needs during production and processing, thereby improving the applicability of the piezoelectric film bulk acoustic resonator. In the embodiment, the acoustic reflection structure is a cavity that passes through one side of substrate 1 to simplify the structure of the substrate 1, reduce the production cost of the substrate 1, and thereby reduce the cost of the piezoelectric film bulk acoustic resonator; meanwhile, the cavity penetrates one side of substrate 1, and the cavity is exposed outside the substrate 1, during the use of the piezoelectric film bulk acoustic resonator, the size and the contour shape of the cavity can be adjusted according to needs to improve the stability and reliability of the piezoelectric film bulk acoustic resonator.

Specifically, as shown in FIG. 3 and FIG. 6, along the thickness direction of the piezoelectric film bulk acoustic resonator, a size of a projection of the bottom electrode 2 towards the substrate 1 is equal to or greater than a size of the cavity 11, and a size of a projection size of the top electrode 4 towards the substrate 1 is less than or equal to the size of the cavity 11.

In the embodiment, the size of the bottom electrode 2 is equal to or greater than the size of the cavity 11, reducing the risk of the bottom electrode 2 tilting into the cavity 11 when the bottom electrode 2 is covered above the cavity 11, thereby improving the stability and reliability of the installation of the bottom electrode 2, and further improving the working stability of the piezoelectric film bulk acoustic resonator.

In any of the above embodiments, the etching insertion layer 5 includes a dielectric material, and the dielectric material is aluminum nitride or silicon nitride.

In the embodiment, the dielectric properties of the aluminum nitride and the silicon nitride are strong, and the aluminum nitride and the silicon nitride have good electrical insulation, the etching insertion layer 5 includes the aluminum nitride or the silicon nitride, which increases the electrical insulation performance of the etching insertion layer 5 and reduces the risk of short circuit of the top electrode 4 caused by etching the insertion layer 5 during the operation of the piezoelectric film bulk acoustic resonator, this improves the working stability of the top electrode 4 and the piezoelectric film bulk acoustic resonator, and this is beneficial for extending the service life of the top electrode 4 and the piezoelectric film bulk acoustic resonator.

In any of the above embodiments, the protruding frame 6 includes a first metal material, and the first metal material includes one of aluminum, molybdenum, tungsten, and ruthenium, or the first metal material is a composite metal formed by at least two of aluminum, molybdenum, tungsten, and ruthenium.

In the embodiment, when the first metal material is aluminum, the first metal material has good ductility, which facilitates the processing of the protruding frame 6 and reduces the processing cost of the protruding frame 6. When the first metal material is molybdenum and tungsten, the first metal material has strong hardness, which improves the structural stability of the protruding frame 6 and is conducive to extending the service life of the protruding frame 6. When the first metal material is tungsten or ruthenium, the chemical property of the first metal material is stable, which reduces the risk of corrosion and oxidation of the protruding frame 6, thereby improving the structural stability of the protruding frame 6, which is conducive to extending the service life of the protruding frame 6.

In any of the above embodiments, the bottom electrode 2 includes a second metal material, and the second metal material includes one of aluminum, molybdenum, tungsten, and ruthenium, or the second metal material is a composite metal formed by at least two of aluminum, molybdenum, tungsten, and ruthenium.

In the embodiment, when the second metal material is aluminum, the second metal material has good ductility, which facilitates the processing of the bottom electrode 2 and reduces the processing cost of the bottom electrode 2. When the second metal material is molybdenum and tungsten, the second metal material has strong hardness, which improves the structural stability of the bottom electrode 2 and is conducive to extending the service life of the bottom electrode 2. When the second metal material is tungsten or ruthenium, the chemical property of the second metal material is stable, which reduces the risk of corrosion and oxidation of the bottom electrode 2, thereby improving the structural stability of the bottom electrode 2, which is conducive to extending the service life of the bottom electrode 2.

In any of the above embodiments, the top electrode 4 includes a third metal material, and the third metal material includes one of aluminum, molybdenum, tungsten, and ruthenium, or the third metal material is a composite metal formed by at least two of aluminum, molybdenum, tungsten, and ruthenium.

In the embodiment, when the third metal material is aluminum, the third metal material has good ductility, which facilitates the processing of the top electrode 4 and reduces the processing cost of the top electrode 4. When the third metal material is molybdenum and tungsten, the third metal material has strong hardness, which improves the structural stability of the top electrode 4 and is conducive to extending the service life of the top electrode 4. When the third metal material is tungsten or ruthenium, the chemical property of the third metal material is stable, which reduces the risk of corrosion and oxidation of the top electrode 4, thereby improving the structural stability of the top electrode 4, which is conducive to extending the service life of the top electrode 4.

It can be understood that the first metal material, the second metal material, and the third metal material can be the same or different.

In any of the above embodiments, the piezoelectric layer 3 includes a piezoelectric material, and the piezoelectric material is one of aluminum nitride, zinc oxide, titanium lead zirconate, lithium niobate and lithium tantalate, alternatively, the piezoelectric material is a composite piezoelectric material formed by at least two of aluminum nitride, zinc oxide, titanium lead zirconate, lithium niobate and lithium tantalate.

In the embodiment, when the piezoelectric material is aluminum nitride, zinc oxide, titanium lead zirconate, lithium niobate, lithium tantalate, the piezoelectric layer 3 has the highest piezoelectric tensor, which is conducive to improving the acoustic wave conversion efficiency of the piezoelectric film bulk acoustic resonator.

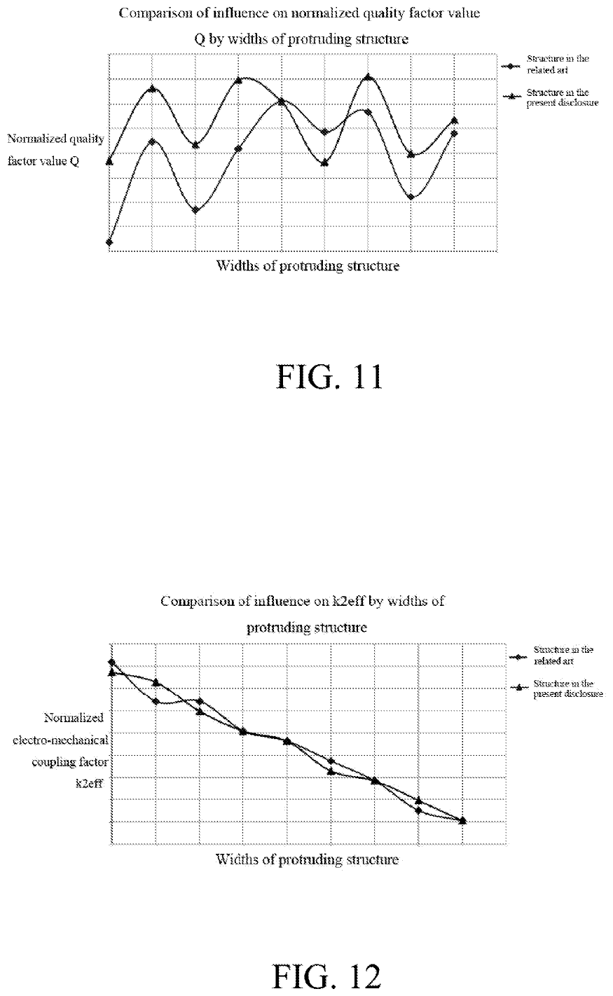

In summary, in the present invention, the quality factor of the piezoelectric film bulk acoustic resonator can be further improved by setting an extending portion and optimizing and adjusting the extension length of the extending portion. As shown in FIG. 11 and FIG. 12, when the etching insertion layer 5 and the protruding frame 6 are both equipped with an extending portion, the first extreme value point, the second extreme value point, and the third extreme value point of the quality factor of the piezoelectric film bulk acoustic resonator of the present invention are significantly increased compared to existing technologies, and the increase in the first extreme value point is the largest. In addition, since the extending portion does not additionally reduce the effective electro-mechanical coupling factor (k2eff) of the piezoelectric film bulk acoustic resonator, selecting the width of the smaller protruding frame 6 corresponding to the first extreme value point allows the piezoelectric film bulk acoustic resonator to have both a high quality factor and a large effective electro-mechanical coupling factor (k2eff).

The above is only the implementation method of the present invention, it should be pointed out that for ordinary technical personnel in this field, improvements can be made without departing from the creative concept of the present invention, but these are all within the scope of protection of the present invention.

What is claimed is:

1. A piezoelectric film bulk acoustic resonator comprising:
a substrate;
a bottom electrode;
a piezoelectric layer;
a top electrode;
an etching insertion layer; and
a protruding frame;
wherein the bottom electrode, the piezoelectric layer, the top layer, and the etching insertion layer are arranged along a thickness direction of the piezoelectric film bulk acoustic resonator; the bottom electrode is located on one side of the substrate, the piezoelectric layer covers one side of the bottom electrode away from the substrate, the top electrode is located on one side of the piezoelectric layer away from the bottom electrode, the etching insertion layer is located on one side of the top electrode away from the piezoelectric layer, and the protruding frame is located on one side of the etching insertion layer away from the top electrode;
a stacking area of the bottom electrode, the piezoelectric layer, the top electrode, and the etching insertion layer constitutes an effective source area of the piezoelectric film bulk acoustic resonator; and
an extending portion is disposed on at least one of the etching insertion layer and the protruding frame, the extending portion is located at an edge of the effective source area, and the extending portion extends towards a direction away from the effective source area along a direction perpendicular to the thickness direction of the piezoelectric thin film bulk acoustic resonator.

2. The piezoelectric film bulk acoustic resonator according to claim 1, wherein a first projection contour of the extending portion is located within a second projection contour of the bottom electrode along the thickness direction of the piezoelectric film bulk acoustic resonator.

3. The piezoelectric film bulk acoustic resonator according to claim 2, wherein an extension length L of the extending portion along the direction perpendicular to the thickness direction of the piezoelectric film bulk acoustic resonator satisfies:
L≥0.5 μm.

4. The piezoelectric film bulk acoustic resonator according to claim 1, wherein the extension portion comprises a first extension portion and a second extension portion, the first extending portion is disposed on the etching insertion layer, and the second extending portion is disposed on the protruding frame;
a first extension length of the first extending portion is the same or different from a second extension length of the second extending portion along an extension direction of the extending portion.

5. The piezoelectric film bulk acoustic resonator according to claim 1, wherein the substrate defines a cavity, the cavity passes through the one side of the substrate along the thickness direction of the piezoelectric film bulk acoustic resonator, and the bottom electrode covers the cavity.

6. The piezoelectric film bulk acoustic resonator according to claim 5, wherein a size of a projection of the bottom electrode towards the substrate along the thickness direction of the piezoelectric film bulk acoustic resonator is equal to or greater than a size of the cavity; and
a size of a projection of the top electrode towards the substrate along the thickness direction of the piezoelectric film bulk acoustic resonator is less than or equal to the size of the cavity.

7. The piezoelectric film bulk acoustic resonator according to according to claim 1, wherein the etching insertion layer comprises a dielectric material, the dielectric material is aluminum nitride or silicon nitride.

8. The piezoelectric film bulk acoustic resonator according to claim 1, wherein the protruding frame comprises a first metal material, the first metal material comprises one of aluminum, molybdenum, tungsten, and ruthenium, or the first metal material is a composite metal formed by at least two of the aluminum, the molybdenum, the tungsten, and the ruthenium.

9. The piezoelectric film bulk acoustic resonator according to claim 1, wherein the bottom electrode comprises a second metal material, the second metal material comprises one of aluminum, molybdenum, tungsten, and ruthenium, or the second metal material is a composite metal formed by at least two of the aluminum, the molybdenum, the tungsten, and the ruthenium; and
the top electrode comprises a third metal material, the third metal material comprises one of the aluminum, the molybdenum, the tungsten, and the ruthenium, or the third metal material is a composite metal formed by at least two of the aluminum, the molybdenum, the tungsten, and the ruthenium.

10. The piezoelectric film bulk acoustic resonator according to claim 1, wherein the piezoelectric layer comprises a piezoelectric material, the piezoelectric material is one of aluminum nitride, zinc oxide, titanium lead zirconate, lithium niobate and lithium tantalate, or the piezoelectric material is a composite piezoelectric material formed by at least two of the aluminum nitride, the zinc oxide, the titanium lead zirconate, the lithium niobate, and the lithium tantalate.
